(19) United States
(12) Patent Application Publication
(10) Pub. No.: US 2026/0219300 A1
(43) Pub. Date: Jul. 30, 2026

(54) CURRENT SENSOR AND METHOD OF MANUFACTURING CURRENT SENSOR

(71) Applicant: Alps Alpine Co., Ltd., Tokyo (JP)

(72) Inventors: Hideaki TAKANO, Miyagi-ken (JP); Shinichi TANAKA, Miyagi-ken (JP); Yasumasa USUBA, Miyagi-ken (JP); Yuu KUMAGAI, Miyagi-ken (JP); Rina SASAKI, Miyagi-ken (JP)

(21) Appl. No.: 19/573,611

(22) Filed: Mar. 20, 2026

Related U.S. Application Data
(63) Continuation of application No. PCT/JP2024/031085, filed on Aug. 29, 2024.

(30) Foreign Application Priority Data
Oct. 3, 2023 (JP) 2023-172072

(51) Int. Cl. G01R 15/20; G01R 33/00; G01R 33/09

(52) U.S. Cl. CPC G01R 15/207; G01R 33/0052; G01R 33/09

(57) ABSTRACT

A current sensor has: a case; a core member formed by laminating a plurality of soft magnetic material plates, the core member being insert-molded to the case; and a magnetic sensor that measures magnetism. The core member has first soft magnetic material plates and second soft magnetic material plates that differ in shape from the first soft magnetic material plates. The second soft magnetic material plate has an exposed portion exposed without being covered by the first soft magnetic material plate when viewed from a lamination direction of the soft magnetic material plates. The outermost layer on at least one surface of the core member is the first soft magnetic material plate.

### CLAIM OF PRIORITY

This application is a Continuation of International Application No. PCT/JP2024/031085 filed on August 29, 2024, which claims benefit of Japanese Patent Application No. 2023-172072 filed on October 3, 2023. The entire contents of each application noted above are hereby incorporated by reference.

### BACKGROUND OF THE INVENTION

### 1. Field of the Invention

The present invention relates to a current sensor that measures a current under test that flows in a bus bar and to a method of manufacturing the current sensor.

### 2. Description of the Related Art

In recent years, to control a power supply system in a vehicle or the like that has various devices, a current sensor that measures a current under test that flows in a device is used.

In Japanese Unexamined Patent Application Publication No. 2010-203910, it is disclosed that, in a current sensor that has a magnetic core member that is equipped with a hollow portion and is in a ring shape, in part of which a clearance is formed, and also has a shield plate, positioning of the magnetic core member relative to a mold is performed by fitting protruding portions in the mold into the hollow portion and gaps in the core member, after which insert molding is carried out by injecting a resin into the mold in which a shield plate is set, with the aim of achieving superior detection precision and reducing manufacturing costs.

In a current sensor equipped with a core member having a gap, a core member is disclosed, in Japanese Unexamined Patent Application Publication No. 2011-43422, that is formed by alternately laminating two types of core members, which are first core members and second core members, in which a insertion hole is formed to suppress a flow of a magnetic flux toward a member extending in a magnetization easing axis direction, with the aim of achieving inexpensive and efficient manufacturing.

In a current sensor having a core member equipped with a gap formed by laminating a plurality of flat plates, which are magnetic bodies, a structure is disclosed, in Japanese Unexamined Patent Application Publication No. 2017-90126, in which protrusions are formed on flat plates at both ends in a lamination direction, with the aim of preventing the core member from undergoing magnetic saturation even when a current becomes large.

In a current sensor equipped with a resinous case and a core member formed by laminating electromagnetic steel plates in which gaps are formed, a structure is disclosed, in Japanese Unexamined Patent Application Publication No. 2018-204978, in which the core member is pressed from both sides by first convex portions formed on an inner peripheral wall of a case due to pressing fitting of the core member into the case so that the core member is positioned and fixed, with the aim of fixing the core member to the case with high positional precision by using a simple structure.

When a core member is to be insert-molded to a case, the core member is held at a predetermined position in a molding mold by pressing pins in the molding mold. Since there is unevenness in the outside dimensions of core members, it is necessary that even the core member having the largest dimension in a tolerance range can be placed in the mold. Basically, therefore, settings are made so that when the core member is placed, a clearance is formed between the core member and the pressing pin.

The core member may be formed from a plurality of laminated thin plate members. Each thin plate member has unevenness in outside dimension. Therefore, as for unevenness in the dimension of the core member in the lamination direction of the thin plate members, unevenness in the dimension of the thin plate member accumulates in correspondence to the number of laminated thin plate members. On the assumption that the core member is formed by laminating n thin plate members each of which has an unevenness of ±a [mm] in the thickness dimension, the unevenness in the dimension of the core member in the lamination direction is ±a × n [mm]. That is, a difference of 2a × n [mm] occurs in dimension between when the core member is formed only from thin plate members with the smallest plate thickness dimension and when the core member is formed only from thin plate members with the largest plate thickness dimension.

Therefore, when the core member is formed by laminating thin plate members, the clearance between the core member and the pressing pin in the lamination direction needs to be increased as the number of laminated thin plate members increases.

As for the current sensors described in Japanese Unexamined Patent Application Publication Nos. 2010-203910, 2011-43422, 2017-90126, and 2018-204978, when the core member formed by laminating a plurality of thin plate members is used, consideration is not taken for unevenness in the dimension of the core member in the lamination direction. Therefore, if the clearance to the pressing pin in the mold becomes large, the amount of positional deviation generated in a soft magnetic body during insert molding becomes large, so there is the fear that measurement precision of the current sensor is lowered.

### SUMMARY OF THE INVENTION

In view of this, in a current sensor having a soft magnetic body in which a plurality of soft magnetic material plates are laminated, the present invention provides a current sensor having superior measurement precision with positional deviation suppressed in the soft magnetic body to a small amount during insert molding and also provides a method of manufacturing the current sensor.

The present invention has a structure below as a means of solving the problems described above.

In a current sensor having a case, a soft magnetic body insert-molded to the case, the soft magnetic body being formed by laminating a plurality of soft magnetic material plates, and a magnetic sensor that measures magnetism, the soft magnetic body has a first soft magnetic material plate and a second soft magnetic material plate that differs in shape from the first soft magnetic material plate; the second soft magnetic material plate has an exposed portion exposed without being covered by the first soft magnetic material plate when viewed from a lamination direction of the soft magnetic material plates; and the outermost layer on at least one surface of the soft magnetic body is the first soft magnetic material plate.

In the current sensor, the soft magnetic body may be a core member and the magnetic sensor may measure magnetism collected by the core member. In the current sensor, the soft magnetic body may be a magnetic shield.

In the above structure, when the soft magnetic body is to be positioned in a mold used for insert molding of the case, pressing pins in the mold can be placed on the exposed portion of the second soft magnetic material plate placed at a position close to both ends of the soft magnetic material plates in their lamination direction. Since the first soft magnetic material plate is used as the outermost layer on at least one surface, the number of laminated layers of the soft magnetic material plates can be reduced at a portion of the soft magnetic body, the portion being held by the pressing pins, as compared with a case in which soft magnetic material plates in the outermost layers at both ends in the lamination direction are held by the pressing pins. Therefore, it becomes possible to reduce a clearance between the soft magnetic body and the pressing pin, the clearance being set according to unevenness (size tolerance) in the thickness dimension of the soft magnetic body.

The soft magnetic body may have a plurality of non-exposed layers, in each of which first soft magnetic material plates are laminated together, and an exposed layer composed of a second soft magnetic material plate, and the non-exposed layer may be laminated on at least one side of the exposed layer.

When the number of laminated layers of the soft magnetic material plates constituting the non-exposed layer and exposed layer is adjusted, the soft magnetic body can be made adaptable to the structure of the current sensor.

In each of the non-exposed layer and exposed layer, a plurality of soft magnetic material plates may be laminated.

When the non-exposed layer is formed by laminating a plurality of soft magnetic material plates, the number of laminated layers of the soft magnetic material plates constituting the exposed layer is made less than when the non-exposed layer is composed of one soft magnetic material plate. When the number of laminated layers of the soft magnetic material plates constituting the exposed layer is reduced, unevenness in the thickness of the exposed layer is reduced, the thickness increasing in proportion to the number of laminated layers. Therefore, it is possible to reduce the clearance between the soft magnetic body and the pressing pin, the clearance being set in correspondence to unevenness in the thickness of the exposed layer, so the current sensor can be made superior in measurement precision with positional deviation suppressed in the soft magnetic body. When the exposed layer is formed by laminating a plurality of soft magnetic material plates, the number of laminated layers of the soft magnetic material plates constituting the non-exposed layer is also made less than when the exposed layer is composed of one soft magnetic material plate. Therefore, it is possible to shorten the lengths of the pressing pins that hold the soft magnetic body, the lengths corresponding to the number of laminated layers in the non-exposed layers, so the risk can be reduced that the pressing pins are damaged during insert molding.

The non-exposed layer may be disposed on each of both ends of the exposed layer, which is sandwiched between the exposed portions, in the lamination direction of the soft magnetic material plates.

When non-exposed layers are placed on both sides of the exposed layer, one of the two pressing pins that hold the exposed layer is less likely to be extremely prolonged than the other pressing pin. Therefore, the risk can be reduced that the pressing pins are damaged during insert molding.

In the non-exposed layer disposed on each of both sides of the exposed layer in the lamination direction of the soft magnetic material plates, the number of laminated layers of the first soft magnetic material plates may be the same.

When a match is made in the number of laminated layers of the first soft magnetic material plates between the non-exposed layers on both sides of the exposed layer, the soft magnetic body takes a symmetric shape with respect to the center of the lamination direction, eliminating any distinction between the front and back sides. Therefore, when the soft magnetic body is to be placed in the mold, the orientation of the soft magnetic body in the lamination direction does not need to be considered, improving productivity.

The exposed layer may be composed of one second soft magnetic material plate. When the exposed layer is formed from one second soft magnetic material plate, a portion, in the soft magnetic body, that is held by the pressing pins is composed of one layer, minimizing unevenness in the thickness dimension of the soft magnetic body. Therefore, it is possible to reduce the clearance between the soft magnetic body and the pressing pin, the clearance being set in correspondence to unevenness.

The soft magnetic body may be a core member, the core member may be formed in a ring shape having a cutout, the case may have an insertion hole that extends through the interior of a ring formed in the core member, and the magnetic sensor may be placed inside or near the cutout.

In the structure described above, a magnetic field, which is derived from a current under test and is collected by the core member, can be detected by the magnetic sensor.

The magnetic sensor may be a magnetoresistive (MR) sensor that can detect magnetism in a direction parallel to a magnetism detection surface, and the magnetism detection surface may be placed outside the cutout so that the magnetism detection surface becomes parallel to a separation direction in the cutout.

When the MR sensor is placed outside the cutout, the MR sensor can be placed at a position at which a magnetic field corresponding to measurement sensitivity is generated, according to the magnitude of the generated magnetic field. Therefore, measurement precision of the current sensor is improved.

On a surface of the case, the surface intersecting the lamination direction of the soft magnetic material plates, the case may have a concave portion, and the exposed portion may be exposed from the deepest portion of the concave portion.

When the exposed portion of the soft magnetic body is exposed from the deepest portion of the concave portion recessed from the surface of the case, the risk of the soft magnetic material plate being corroded can be more greatly suppressed than when the exposed portion is exposed from the surface of the case.

The case may have a covering portion placed inside the concave portion, the covering portion covering the exposed portion exposed at the concave portion.

Since the covering portion covers the exposed portion, it is possible to more reliably prevent, for example, a liquid from entering the interior of the case from the clearance between the soft magnetic material plate and a resin forming the case.

A method of manufacturing a current sensor is to manufacture a current sensor in which a soft magnetic body, which is formed by laminating a plurality of soft magnetic material plates, is insert-molded to a case. The soft magnetic body has a first soft magnetic material plate, which is disposed in the outermost layer on at least one surface, and a second soft magnetic material plate that differs in shape from the first soft magnetic material plate, the second soft magnetic material plate having an exposed portion exposed without being covered by the first soft magnetic material plate. When a pair of pressing pins included in a molding mold hold the soft magnetic body, at least one of the pair of pressing pins is brought into contact with the exposed portion. A molten molding resin is filled into the molding mold in a state in which at least one of the pair of pressing pins is in contact with the exposed portion.

Since at least one of the pair of pressing pins is brought into contact with the exposed portion, it is possible to hold a portion in which the number of laminated layers is less than the number of laminated layers of the soft magnetic material plates constituting the soft magnetic body. Therefore, it is possible to reduce a clearance between the soft magnetic body and the pressing pin, the clearance being formed in correspondence to unevenness in the thickness dimension of the soft magnetic body.

The present invention can reduce a clearance between a soft magnetic material plate and a pressing pin in a mold used during insert molding. When this clearance is reduced so that positional deviation, which may occur during insert molding, of the soft magnetic material body is reduced and a drop of positional deviation due to the positional deviation is suppressed, it is possible to provide a current sensor having superior measurement precision.

### BRIEF DESCRIPTION OF THE DRAWINGS

FIG. 1 is a perspective view illustrating the appearance of a current sensor in a first embodiment of the present invention;

FIG. 2 is an exploded perspective view schematically illustrating the structure of the current sensor in FIG. 1;

FIG. 3 is a perspective view illustrating an example of the structure of a conventional core member;

FIG. 4 is a plan view schematically illustrating a relationship between a core member in an area P in FIG. 3 and pressing pins in a mold;

FIG. 5 is a perspective view illustrating the structure of a core member in the current sensor in FIG. 1;

FIG. 6 is a partial sectional view schematically illustrating a relationship between the core member in an area P in FIG. 5 and pressing pins in a mold:

FIG. 7 is a partial sectional view schematically illustrating a relationship among the core member, a case, and the pressing pins in the mold as taken along line VII-VII in FIG. 1;

FIG. 8 is a partial sectional view schematically illustrating a relationship between the core member and the case as taken along line VIII-VIII in FIG. 1;

FIG. 9 is a partial sectional view schematically illustrating a variation of the relationship between the core member and the case in FIG. 8;

FIG. 10 is a side view schematically illustrating the structure of the core member in the current sensor in FIG. 1;

FIG. 11 is a side view schematically illustrating the structure of a variation of the core member in FIG. 10;

FIG. 12 is a side view schematically illustrating the structure of another variation of the core member in FIG. 10;

FIG. 13 is a side view schematically illustrating the structure of yet another variation of the core member in FIG. 10;

FIG. 14 is a side view schematically illustrating the structure of still another variation of the core member in FIG. 10;

FIG. 15 is a flowchart illustrating a manufacturing method in a first embodiment of the present invention;

FIG. 16 is a perspective view illustrating the appearance of a current sensor in a second embodiment of the present invention; and

FIG. 17 a sectional view schematically illustrating the structure of the current sensor as taken along line XVII-XVII in FIG. 16.

### DESCRIPTION OF THE PREFERRED EMBODIMENTS

Embodiments of the present invention will be described below with reference to the attached drawings. Identical members are assigned identical reference characters in the drawings and descriptions will be appropriately omitted. A reference coordinate system is appropriately illustrated on the drawings to indicate the positional relationship of members. In the reference coordinate system, the direction of the width dimension of a bus bar is the X direction; the extending direction of the bus bar, the extending direction being orthogonal to the X direction, is the Y direction; and the lamination direction of the bus bar and a magnetic sensor, the lamination direction being orthogonal to the X direction and Y direction, is the Z direction. The X direction is the direction of a sensitivity axis of the magnetic sensor. The Y direction and Z direction are orthogonal to the sensitivity axis.

### First Embodiment

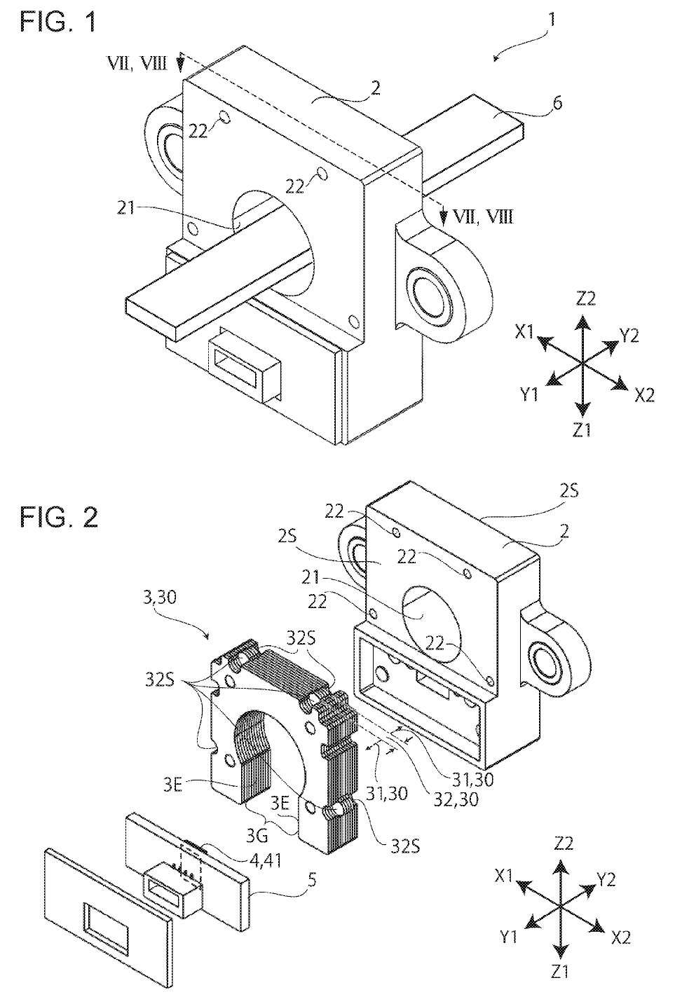

FIG. 1 is a perspective view illustrating the appearance of a current sensor 1 in this embodiment. FIG. 2 is an exploded perspective view schematically illustrating the structure of the current sensor 1 in FIG. 1.

A core member 3 is insert-molded to a case 2 and the core member 3 and case 2 are integrated together. In the exploded perspective view in FIG. 2, however, the core member 3 is removed from the case 2 for convenience of explanation. The current sensor 1 has the case 2, the core member 3 (soft magnetic body), and a magnetic sensor 4.

The case 2 is formed from a resin or the like. The core member 3 is insert-molded to the case 2. The case 2 has a insertion hole 21 that extends through the inside of a ring formed in the core member 3. A bus bar 6 is passed through the insertion hole 21.

The core member 3 is made of a soft magnetic material. A plurality of soft magnetic material plates 30 are laminated to form the core member 3. The soft magnetic material plates 30 are fixed to each other by laser welding, crimping, or the like and are integrated together. The core member 3 has a cutout 3G formed between two end faces 3E facing each other in the X direction. The core member 3 is ring-shaped so that a bus bar 6 can pass through the core member 3 when viewed along the lamination direction. On a surface 2S of the case 2, the surface 2S intersecting the lamination direction in the core member 3, concave portions 22 are formed at portions at which pressing pins were positioned during insert molding.

When a current under test flows in the bus bar 6, a magnetic field is formed along the core member 3. Specifically, a magnetic field that is less susceptible to the effect of a disturbance is generated between the end faces 3E of the core member 3, and the magnetic field between the end faces 3E is detected by the magnetic sensor 4. Although an aspect in which the bus bar 6 has been passed through the core member 3 will be described below, the present invention can also be practiced in an aspect in which a conducting wire other than the bus bar 6 is passed through the core member 3. In this case, the current sensor 1 measures a current under test that flows in the conducting wire.

The magnetic sensor 4 is a magnetoresistive (MR) sensor that can detect magnetism in a predetermined direction parallel to a magnetism detection surface 41. The magnetic sensor 4 can be surface-mounted on a substrate 5. The direction in which the magnetic sensor 4 described above can detect magnetism will be taken as a sensitivity axis direction. In this embodiment, the magnetism detection surface 41 is placed outside the cutout 3G (on the Y1 side) so that the magnetism detection surface 41 becomes parallel to a separation direction in the cutout 3G in the core member 3, that is, the X direction in which the two end faces 3E face each other, and that the sensitivity axis direction becomes parallel to the X direction. When the magnetic sensor 4 is placed outside the cutout 3G, the magnetic sensor 4 can be placed at a position at which a magnetic field corresponding to measurement sensitivity is generated, according to the magnitude of the generated magnetic field. Therefore, measurement precision of the current sensor 1 is improved. However, the magnetic sensor 4 may be placed in the cutout 3G in the core member 3 or at the periphery of the cutout 3G (on the Y2 side, on the Z1 side, or the like)

A magnetoresistive element such as a giant magnetoresistive (GMR) element or a tunnel magnetoresistive (TMR) element may be used as a magnetism detection element included in the magnetic sensor 4. The magnetic sensor 4 may include a hall element or the like as a magnetism detection element, instead of a magnetoresistive element.

The sensitivity axis on the magnetism detection surface 41 of the magnetic sensor 4 is oriented in a direction parallel to the X axis along which the end faces 3E of the core member 3 face each other. An induced magnetic field collected by the core member 3 includes a large X‑direction component in the vicinity of the magnetism detection surface 41 of the magnetic sensor 4, the induced magnetic field being generated when a current under test flows in the bus bar 6. Therefore, when the magnetic sensor 4 is placed so that the sensitivity axis becomes parallel to the X direction, magnetism generated by the bus bar 6 can be precisely detected.

The bus bar 6 is a conductive material through which a current under test, which is a measurement target, flows, the conductive material being made of copper, brass, aluminum, or the like. The bus bar 6 is formed in a plate shape and is placed so as to pass through the core member 3 formed in a ring shape. Although, in the current sensor 1, the bus bar 6 is in a plate shape, the bus bar 6 is not limited to a plate shape. For example, when the bus bar 6 is cut along the X-Z plane, the cross section of the bus bar 6 may be in a circular shape.

The soft magnetic material plates 30 constituting the core member 3 are composed of two types of plate-like bodies, which are soft magnetic material plates 31 (first soft magnetic material plates) and soft magnetic material plates 32 (second soft magnetic material plates). The soft magnetic material plate 32 differs in shape from the soft magnetic material plate 31. An exposed portion 32S is included in the soft magnetic material plate 32, the exposed portion 32S being exposed without being covered by the soft magnetic material plate 31 when viewed along the Y direction, which is the lamination direction of the soft magnetic material plates 30. In the core member 3 illustrated in FIG. 2, the soft magnetic material plate 30 in the outermost layer of the core member 3 is the soft magnetic material plate 31 both on the Y1 side and on the Y2 side. However, on the surface on at least one of the Y1 side and Y2 side, the outermost layer only needs to be the soft magnetic material plate 31, as described later as a variation.

When soft magnetic material plates 30 having a thin thickness are laminated, the collection property of the core member 3 is improved. It suffices to design the number of laminated layers and the thickness of the soft magnetic material plate 30 in relation to performance required for the core member 3.

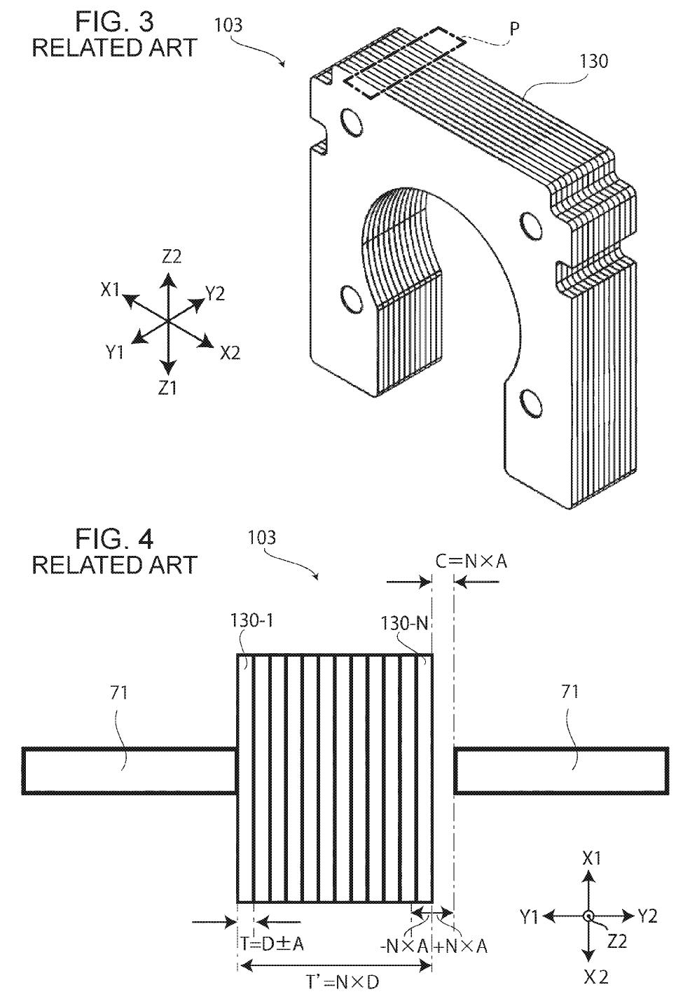

FIG. 3 is a perspective view illustrating an example of the structure of a conventional core member 103. FIG. 4 is a plan view schematically illustrating a relationship between the core member 103 in an area P in FIG. 3 and pressing pins in a mold.

With reference to these drawings, problems will be described below that were found by the inventors when the core member 103 formed by laminating a plurality of soft magnetic material plates 130 is insert-molded to integrate the core member 103 with the case 2. In the description below, the terms design reference dimension and size tolerance are used, so supplemental descriptions will be given to these terms. If a dimension s (mm) of a region is managed under s = p (mm) ±q (mm), for example, p (mm) and ±q (mm) will be respectively described as a design reference dimension and size tolerance. Values on the plus side and minus side of size tolerance may be different values such as, for example, +0.05 (mm)/-0.02 (mm).

When the core member 103 is to be fixed at a predetermined position in a mold and then is to be insert-molded to the case 2 (see FIGS. 1 and 2), the core member 103 is positioned in the Y direction, which is the lamination direction, with the core member 103 sandwiched by pressing pins 71 in the mold. At this time, the distance between the pressing pins 71 is made slightly larger than a predetermined thickness dimension in consideration of unevenness in the thickness dimension of the core member 103. That is, it is necessary to enable the core member 103 to be placed in the mold and enable the core member 103 to be insert-molded even if the thickness dimension of the core member 103 is larger than the design reference dimension but still within the range of the size tolerance.

Therefore, the mold is designed so that when the core member 103 machined with the thickness dimension matching the design reference dimension is placed in the mold, a clearance C is formed between the core member 103 and the pressing pin 71. That is, the clearance C is formed between the pressing pin 71 and the core member 103 in correspondence to the unevenness of the thickness dimension of the core member 103. In other words, the clearance C is formed so that even if the thickness dimension of the core member 103 is the largest within the range of the size tolerance, the core member 103 can be placed in the mold. Thus, even if the thickness dimension of the core member 103 is large due to unevenness, it is possible to prevent the occurrence of the problem with the mold during positioning of the core member 103.

When many soft magnetic material plates 130 are laminated in the core member 103, the range of unevenness in thickness dimension is likely to become larger than when a core member is formed in a shape of one block. When, for example, a thickness dimension T of the soft magnetic material plate 130 is managed under a design reference dimension D and a size tolerance ±A and the core member 103 is formed by laminating N soft magnetic material plates 130, the thickness dimension T' of the core member 103 needs to be managed under T' = (N × D) ± (N × A). That is, there is the possibility that unevenness occurs in the range of ±(N × A) at maximum unlike the design reference dimension N × D. In view of this, the clearance C described above needs to be N × A in consideration of a case in which the thickness dimension of the core member 103 is the largest dimension (N × (D + A)) within the range of the size tolerance.

If it is assumed that the plate thickness dimensions of soft magnetic material plates 130-1 to 130-N forming the core member 103, that is, the thickness dimensions T, are all thinner than the design reference dimension D by A, the thickness dimension T' of the core member 103 is smaller than the design reference dimension N × D by about N × A. In this case, a clearance of 2N × A, resulting from adding N × A of the clearance C to unevenness N × A, is formed between the pressing pin 71 in the mold and the core member 103. Therefore, there is the risk that the core member 103 is pressed due to a flow of a resin injected into the mold during insert molding and the position of the core member 103 thereby deviates in the Y direction by (2N × A). When the core member 103 is formed by laminating 12 soft magnetic material plates 130, for example, the soft magnetic material plates 130, the thickness dimensions of which are managed under a design reference dimension D of 0.5 mm and a size tolerance of ±0.04 mm, are all machined to 0.5 - 0.04 mm, there is the risk that the position of the core member 103 deviates in the Y direction by a maximum of 0.96 mm.

If the position of the core member 103 in the case 2 deviates during insert molding, a deviation occurs in the positional relationship between the core member 103 and the magnetic sensor 4. Thus, measurement precision of the current sensor 1 is lowered.

In view of this, the core member 3 in the current sensor 1 in this embodiment has a structure to suppress the clearance C corresponding to unevenness between the core member 3 and the pressing pin 71 in the mold and unevenness in the thickness dimension of a portion sandwiched by the pressing pins 71. When the clearance C and unevenness in thickness dimension are reduced to reduce the amount of positional deviation, which may occur during insert molding, of the core member 3, it is possible to provide the current sensor 1, with high measurement precision, in which the core member 103 and magnetic sensor 4 are placed at predetermined positions.

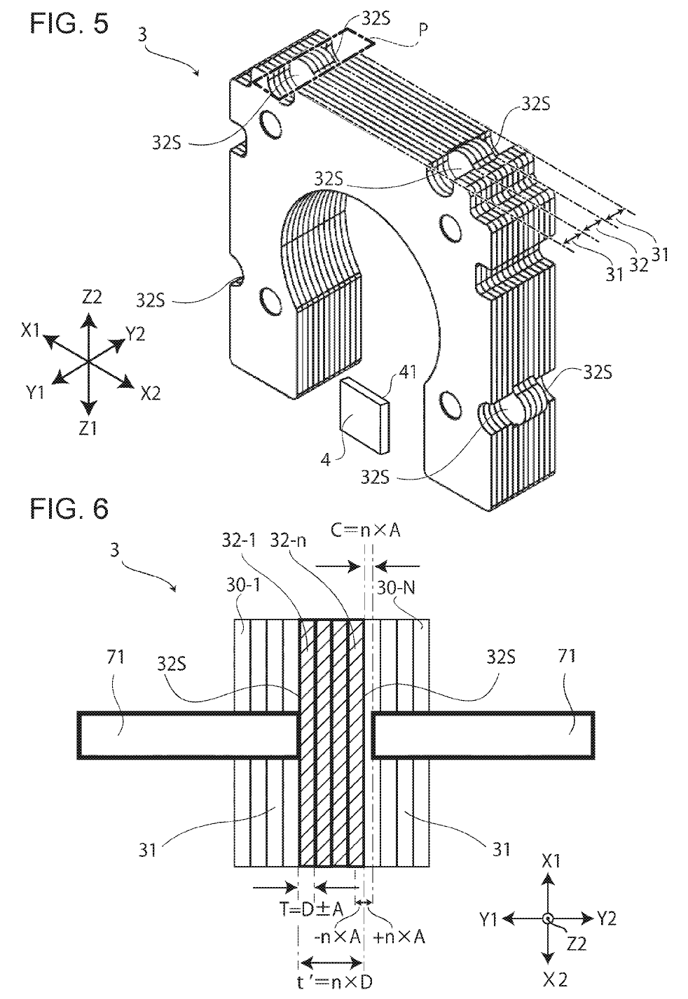

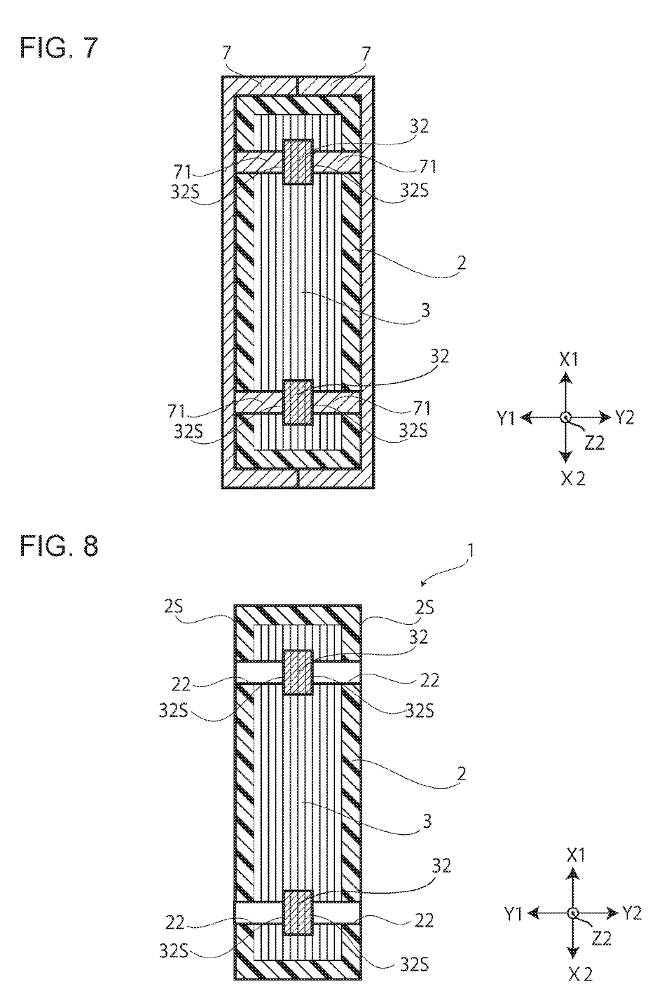

FIG. 5 is a perspective view illustrating the structure of the core member 3 in the current sensor 1 in FIG. 1. FIG. 6 is a partial sectional view schematically illustrating a relationship between the core member 3 in an area P in FIG. 5 and the pressing pins 71 in the mold. The drawing is a partial sectional view in which part of the exposed portion 32S of the soft magnetic material plate 32 is cut along a rectangular plane illustrated as the area P, illustrating a portion protruding from an edge, on the Z2 side, that is part of the outer edges of the soft magnetic material plate 32, the portion being hatched. FIG. 7 is a partial sectional view schematically illustrating a relationship among the core member 3, the case 2, and the pressing pins 71 in a mold 7 as taken along line VII-VII in FIG. 1.

As illustrated in these drawings, the core member 3 in the current sensor 1 has two types of soft magnetic material plates 30, which are soft magnetic material plates 31 and soft magnetic material plates 32. The soft magnetic material plate 32 has exposed portions 32S, which are exposed when the core member 3 is viewed along the lamination direction (Y direction). In other words, when the soft magnetic material plate 31 and soft magnetic material plate 32 are laminated side by side and are viewed from the same side as the soft magnetic material plate 31, the exposed portion 32S is a portion not covered by the soft magnetic material plate 31 (portion protruding from the soft magnetic material plate 31). In the core member 3, the exposed portion 32S of the soft magnetic material plate 32 is formed as a circular plane that has a protruding portion as well as a portion exposed from recessed portion of the outline of the soft magnetic material plate 31. However, the outside shape of the exposed portion 32S is not limited to a circle. The exposed portion 32S may also be composed of only one of the portion exposed from the recessed portion and the portion protruding toward the Z2 side.

When soft magnetic material plates 31 and soft magnetic material plate 32 are to be laminated as the core member 3 in the current sensor 1, at least one end of the core member 3 in the lamination direction is formed with the soft magnetic material plate 31. When the core member 3 is placed in the mold 7, the pressing pins 71 are brought into contact with portions of the exposed portions 32S for holding purposes. In this type of structure, at least the soft magnetic material plate 31 placed at one end of the core member 3 in the lamination direction is not held by the pressing pins 71. Therefore, when the clearance C is to be formed between the core member 3 and the pressing pin 71, unevenness in the plate thickness dimension does not need to be considered for the soft magnetic material plate 31 placed at one end of the core member 3 in the lamination direction. Thus, the dimension of the clearance C can be reduced. Unevenness toward the minus side is also reduced in the dimension of the portion held by the pressing pins 71. Therefore, the amount of positional deviation of the core member 3 during insert molding can be made less than when the core member 3 is composed of one type of soft magnetic material plates 30. It is also possible to further reduce the amount of positional deviation of the core member 3 during insert molding by placing more laminated layers of soft magnetic material plates 31 at one end or by placing soft magnetic material plates 31 at both ends.

That is, even when the thickness dimensions T of soft magnetic material plates 30-1 to 30-N have been all made thinner than the design reference dimension D by A, only soft magnetic material plates 32-1 to 32-n are sandwiched by the pressing pins 71 in the mold 7, as illustrated in FIGS. 5 and 6. Therefore, assuming that the number of laminated layer of soft magnetic material plates 32 is n, the clearance C, which is set in consideration of a case in which the maximum unevenness occurs, is n ×A (n < N).

When the thickness dimensions T of soft magnetic material plates 30-1 to 30-N have been all made thinner than the design reference dimension D by A, the thickness dimension T' of the core member 3 is made thinner than the design reference dimension N × D by about N × A. That is, when soft magnetic material plates 30 are placed at one end and another end of the laminated soft magnetic material plates 30, if a structure is taken in which the core member 3 is sandwiched by the pressing pins 71 in the mold 7, the clearance between the core member 3 and the pressing pin 71 becomes wider by N × A than when the thickness dimensions T of the soft magnetic material plates 30 are all equal to the design reference dimension D (see FIG. 4).

In contrast to this, when a portion of the exposed portion 32S of the core member 3 is sandwiched by the pressing pins 71 in the mold 7, a thickness dimension t' of a layer in which soft magnetic material plates 32 positioned between the pressing pins 71 in the mold 7 are laminated is made smaller than a design reference dimension n × D by about n × A. That is, when a portion of the exposed portion 32S of the core member 3 is sandwiched by the pressing pins 71 in the mold 7, the clearance between the core member 3 and the pressing pin 71 becomes wider by n × A than when the thickness dimensions T of soft magnetic material plates 30 are all equal to the design reference dimension D.

Since n < N, when a portion of the exposed portion 32S of the core member 3 is sandwiched by the pressing pins 71 in the mold 7, even if the thickness dimensions T of the soft magnetic material plates 30 are all the smallest within size tolerance, an amount by which the clearance between the core member 3 and the pressing pins 71 is widened can be reduced.

In the structure in this embodiment, it is possible to reduce the size of the clearance C, which is set between the pressing pin 71 and the core member 3 in consideration of unevenness in the thickness dimensions of soft magnetic material plates 30, and to reduce an amount by which the clearance C is widened even if the thickness dimensions T of the soft magnetic material plates 30 are all the smallest within size tolerance. Therefore, it is possible to reduce the maximum value of the amount of deviation of the core member 103 in the Y direction; the deviation may occur due to a flow of a resin during insert molding.

For example, a case will be assumed in which the core member 3 is formed by laminating 12 soft magnetic material plates 30 with a thickness dimension T of 0.5 mm and an evenness of 0.04-mm, and four of the 12 soft magnetic material plates 30 are soft magnetic material plates 32 laminated successively. In this case, the thickness dimension t' of a portion sandwiched by the pressing pins 71 is smaller than a predetermined thickness of 2.0 mm (= 4 × 0.5 mm) by 0.16 mm (= 4 × 0.04 mm) at maximum, and the clearance C is 0.16 mm (= 4 × 0.04 mm). Therefore, the maximum value of positional deviation, which may occur in the core member 3 during insert molding to the case 2, is 0.32 mm. Thus, it is possible to suppress positional deviation, which may occur in the core member 3 in the Y direction, to one-third 0.96 mm taken for the core member 103 illustrated in FIG. 4.

As described above, in the current sensor 1, the core member 3 is composed of soft magnetic material plates 31 having a cutout and soft magnetic material plates 32 not having a cutout. Therefore, when, instead of sandwiching all soft magnetic material plates 30 (soft magnetic material plates 31 and soft magnetic material plates 32) constituting the core member 3 by using the pressing pins 71, a portion (specifically, the exposed portion 32S) of the soft magnetic material plate 32 is sandwiched, it is possible to reduce the number of soft magnetic material plates 30 sandwiched by the pressing pins 71. This can reduce unevenness in the thicknesses of the portions sandwiched by the pressing pins 71 when the position of the core member 3 in the lamination direction is to be determined during insert molding.

That is, in the mold 7 used for insert molding, the core member 3 can be held by holding portions at which the number of laminated layers is small with respect to a total number of laminated layers of soft magnetic material plates 30. This makes it possible to reduce the clearance C between the core member 3 and the pressing pin 71 in the mold 7 and to reduce unevenness in thickness at portions at which soft magnetic material plates 32 are laminated. Therefore, by reducing positional deviation, which may occur in the core member 3 in the Y direction during insert molding to the case 2, the current sensor 1 with superior measurement precision can be provided.

FIG. 8 is a partial sectional view schematically illustrating a relationship between the core member 3 and the case 2 as taken along line VIII-VIII in FIG. 1. As illustrated in the drawing, in a state in which the core member 3 has been insert-molded and the mold 7 is removed, the position, in the mold 7, at which the pressing pin 71 was present becomes the concave portion 22. Specifically, the concave portion 22 is formed in the surface 2S of the case 2, the surface 2S intersecting the Y direction, which is the lamination direction in the core member 3, and the exposed portion 32S is exposed from the deepest portion of the concave portion 22. In the current sensor 1, the exposed portion 32S, which is a plated surface, of the core member 3 is exposed at the deepest portion of the concave portion 22, so corrosion of the core member 3 can be suppressed.

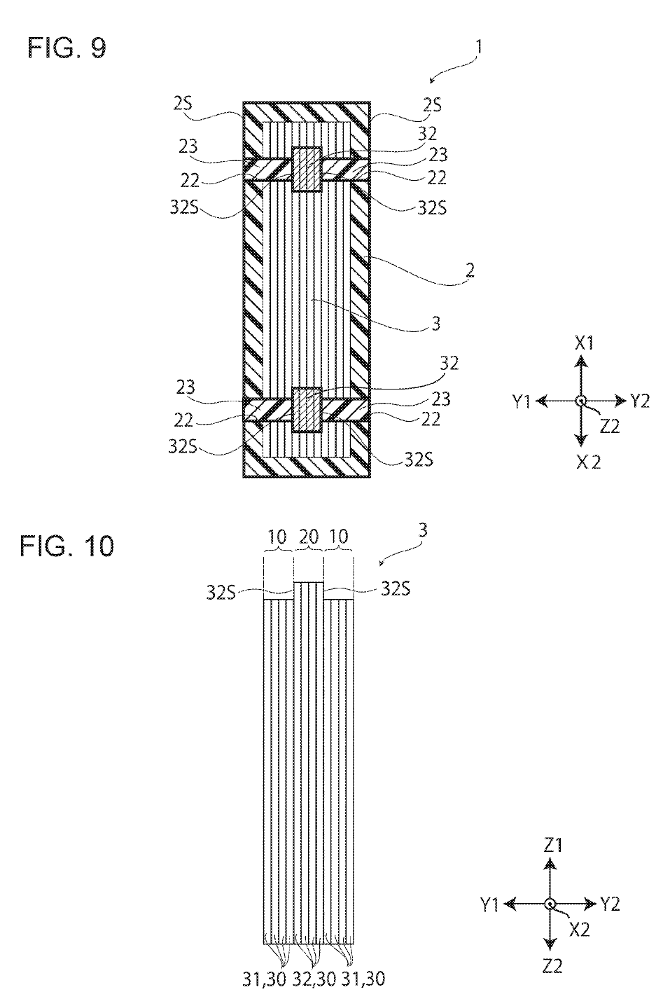

FIG. 9 is a partial sectional view schematically illustrating the relationship between the core member 3 and the case 2 in the current sensor 1 that is a variation of FIG. 8. As illustrated in the drawing, the case 2 may have a covering portion 23 that covers the exposed portion 32S exposed from the deepest portion of the concave portion 22. Since the covering portion 23 covers the concave portion 22, it is possible to prevent, for example, a liquid from entering the interior of the case 2 from the clearance between the core member 3 and a resin forming the case 2. If the covering portion 23 can cover the concave portion 22, the material of the covering portion 23 does not matter. For example, a resin different from the resin used for insert molding or the like can be used. In this variation, the concave portion 22 is filled with a resin to form the covering portion 23. However, a method such as press-fitting or pasting of another member may be used to form the covering portion 23.

FIG. 10 is a side view schematically illustrating the structure of the core member 3 in the current sensor 1 in FIG. 1. The core member 3 illustrated in the drawing is structured so that four soft magnetic material plates 31, four soft magnetic material plates 32, and four soft magnetic material plates 31 are laminated in that order from the Y1 side toward the Y2 side.

The core member 3 has a plurality of non-exposed layers 10 in each of which soft magnetic material plates 31 are laminated together, and also has an exposed layer 20 in which soft magnetic material plates 32 are laminated together and that has exposed portions 32S at both ends in the Y direction. The non-exposed layers 10 are laminated at both ends of the exposed layer 20. In each of the non-exposed layer 10 and exposed layer 20, a plurality of soft magnetic material plates 30 are laminated.

In the structure in which non-exposed layers 10 composed of soft magnetic material plates 31 are disposed at both ends of the exposed layer 20 composed of several layers of soft magnetic material plates 30 (specifically, soft magnetic material plates 32) as in the core member 3 illustrated in FIG. 10, the core member 3 is provided in which the pressing pin 71 is less likely to be damaged.

For example, if the core member 3 is structured so that the non-exposed layer 10 is disposed only on one side (for example, the Y1 side) of the exposed layer 20, when the core member 3 is placed in the mold 7 illustrated in FIG. 7, the pressing pin 71 disposed on the Y1 side becomes longer than the pressing pin 71 disposed on the Y2 side. The pressing pin 71 is very thin metal rod, so the longer the pressing pin 71 is, the more likely the pressing pin 71 is to be broken when a force is applied to the top in the X direction or Z direction. That is, in this structure, the exposed layer 20 is positioned in the vicinity of the center in the lamination direction, and one pressing pin 71 (see FIGS. 6 and 7) is not extremely prolonged, so the pressing pin 71 becomes less likely to be damaged. Also, when the number of laminated layers of the soft magnetic material plates 31 constituting the non-exposed layer 10 is adjusted, the core member 3 can be adapted to the structure of the current sensor 1.

When the core member 3 is structured so that non-exposed layers 10 that include the same number of laminated layers are disposed at both ends of the exposed layer 20 as illustrated in FIG. 10, orientation (specifically, the rear or front) in which the core member 3 is placed in the mold 7 (see FIG. 7) does not need to be considered. Therefore, workability and productivity are improved, so manufacturing costs can be suppressed.

### Variations

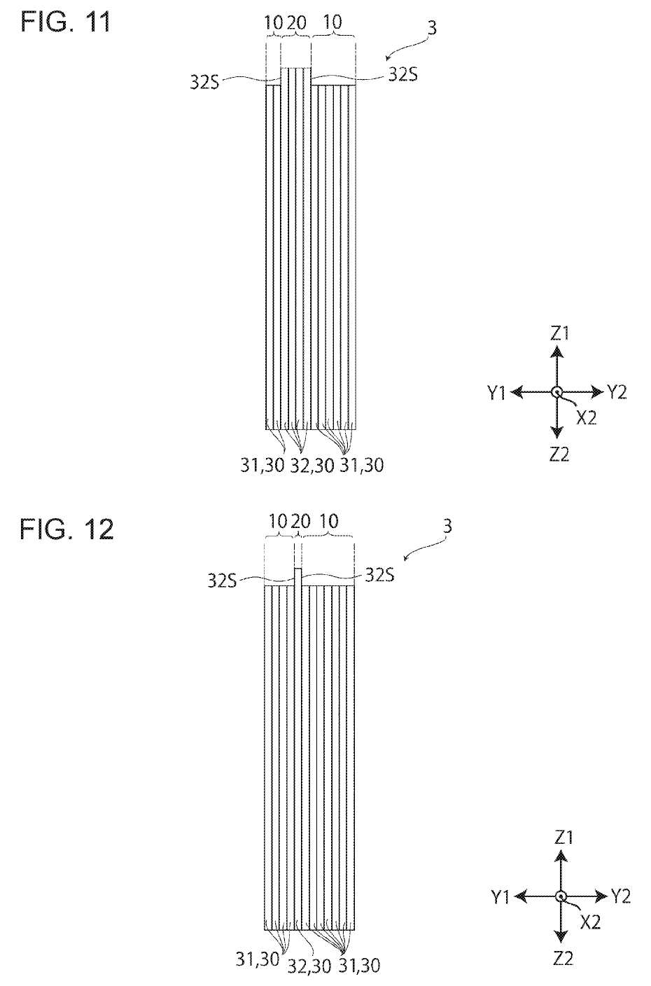

FIG. 11 is a side view schematically illustrating the structure of a variation of the core member 3 in FIG. 10. The drawing illustrates the core member 3 structured so that the non-exposed layer 10 composed of two layers of soft magnetic material plates 31, the exposed layer 20 composed of four layers of the soft magnetic material plate 32, and the non-exposed layer 10 composed of six layers of soft magnetic material plates 31 are laminated in that order from the Y1 side toward the Y2 side. Thus, a different number of laminated layers of soft magnetic material plates 31 may constitute each of the non-exposed layers 10 disposed on both sides of the exposed layer 20.

FIG. 12 is a side view schematically illustrating the structure of another variation of the core member 3 in FIG. 10. The drawing illustrates the core member 3 structured so that the non-exposed layer 10 composed of four layers of soft magnetic material plates 31, the exposed layer 20 composed of one layer of the soft magnetic material plate 32, and the non-exposed layer 10 composed of seven layers of soft magnetic material plates 31 are laminated in that order from the Y1 side toward the Y2 side. Thus, the exposed layer 20 may be composed of one soft magnetic material plate 32. During insert molding, therefore, it is only necessary to consider unevenness for a single metal plate of the soft magnetic material plate 32, and lamination tolerance does not need to be considered. Therefore, it is possible to reduce positional displacement of the core member 3.

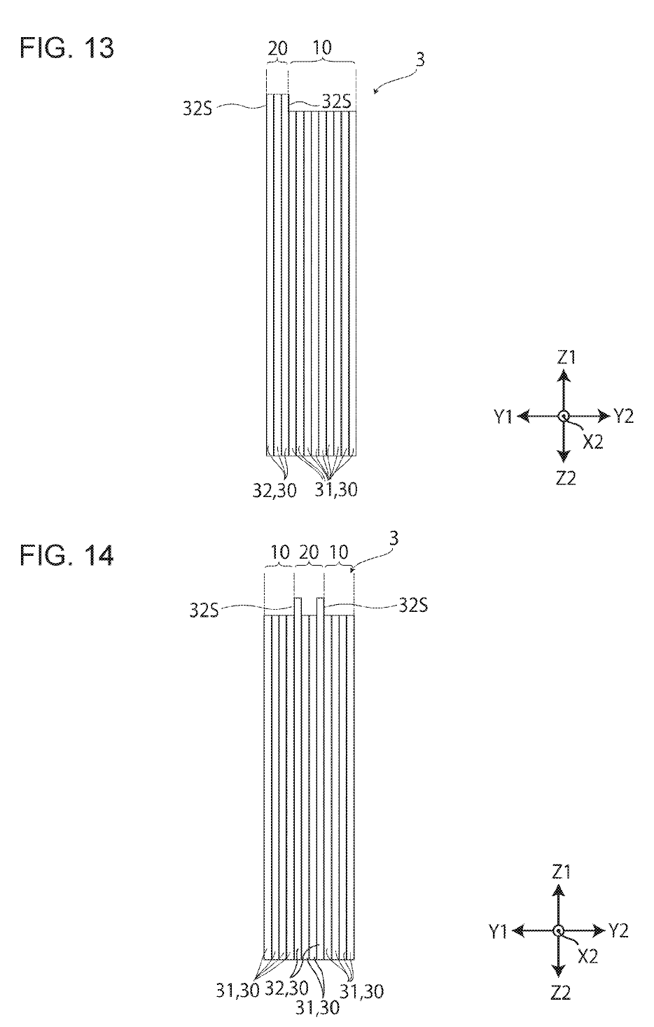

FIG. 13 is a side view schematically illustrating the structure of yet another variation of the core member 3 in FIG. 10. The drawing illustrates the core member 3 structured so that the exposed layer 20 composed of three layers of soft magnetic material plates 32 and the non-exposed layer 10 composed of nine layers of the soft magnetic material plate 31 are laminated in that order from the Y1 side toward the Y2 side. Thus, the non-exposed layer 10 may be disposed only on one side of the exposed layer 20.

As in the core member 3 illustrated in FIG. 13, when the exposed layer 20 is disposed on the Y1 side close to the magnetic sensor 4, it becomes easy to dispose the magnetic sensor 4 and core member 3 at predetermined positions. Therefore, from the viewpoint of manufacturing the current sensor 1 with superior measurement precision, a structure is preferable in which the non-exposed layer 10 is provided only on a side opposite to the magnetic sensor 4 with respect to the exposed layer 20 (see FIGS. 2 and 5).

FIG. 14 is a side view schematically illustrating the structure of still another variation of the core member 3 in FIG. 10. The drawing illustrates the core member 3 structured so that the non-exposed layer 10 composed of four layers of soft magnetic material plates 31, the exposed layer 20 in which two layers of soft magnetic material plate 31 are sandwiched between soft magnetic material plates 32, and the non-exposed layer 10 composed of four layers of soft magnetic material plates 31 are laminated in that order from the Y1 side toward the Y2 side. Thus, the exposed layer 20 may be structured so that soft magnetic material plates 31 are placed between soft magnetic material plates 32 at both ends in the lamination direction. In this structure, the surface area of the exposed layer 20 is enlarged and an area in contact with the resin is thereby enlarged, so tight adhesion is improved between the core member 3 and resin injected during insert molding.

### Manufacturing Method

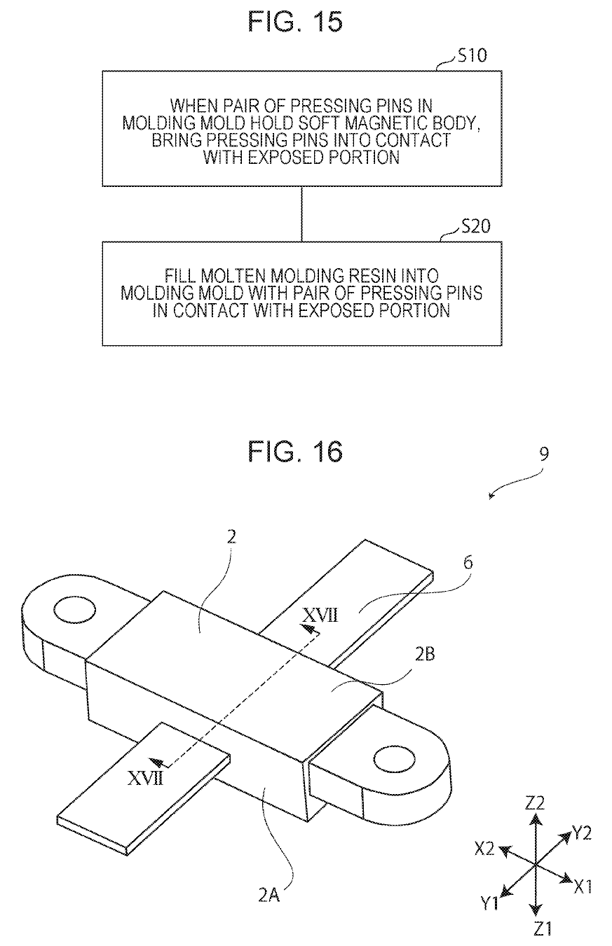

FIG. 15 is a flowchart illustrating a manufacturing method in this embodiment. As illustrated in the drawing, the manufacturing method in this embodiment is to manufacture the current sensor 1 in which the core member 3 (soft magnetic body), which is formed by laminating a plurality of soft magnetic material plates 30, is insert-molded to the case 2. The core member 3 used in this manufacturing method has the soft magnetic material plate 31 disposed in the outermost layer on at least one surface as well as the soft magnetic material plate 32 different in shape from the soft magnetic material plate 31, the soft magnetic material plate 32 having the exposed portion 32S, which is exposed without being covered by the soft magnetic material plate 31.

In insert molding, a member to be buried in a resin is placed at a predetermined position in a mold with pressing pins or the like, after which the mold is filled with the resin.

In the manufacturing method in this embodiment, first, when a pair of pressing pins 71 included in the mold 7 (molding mold) hold the core member 3, at least one of the pair of pressing pins 71 is brought into contact with the exposed portion 32S (S10). Next, a molten molding resin is filled into the mold 7 in a state in which at least one of the pair of pressing pins 71 is in contact with the exposed portion 32S (S20, see FIGS. 5 to 7).

Since at least one of the pair of pressing pins 71 is brought into contact with the exposed portion 32S, the number of laminated layers of the soft magnetic material plates 30 to be held can be made less than when both ends of the soft magnetic material plates 30 constituting the core member 3 are held. Therefore, it is possible to reduce the clearance C between the core member 3 and the pressing pin 71 in the mold 7, the clearance C being formed in correspondence to unevenness in the thickness dimension of the core member 3. Since the number of laminated layers of the soft magnetic material plates 30 held by the pressing pins 71 is reduced, the range of unevenness of the dimension of the sandwiched portion is also reduced. Therefore, when the amount of positional deviation, which occurs during insert molding, of the core member 3, is reduced, it is possible to manufacture the current sensor 1 with high measurement precision.

### Second Embodiment

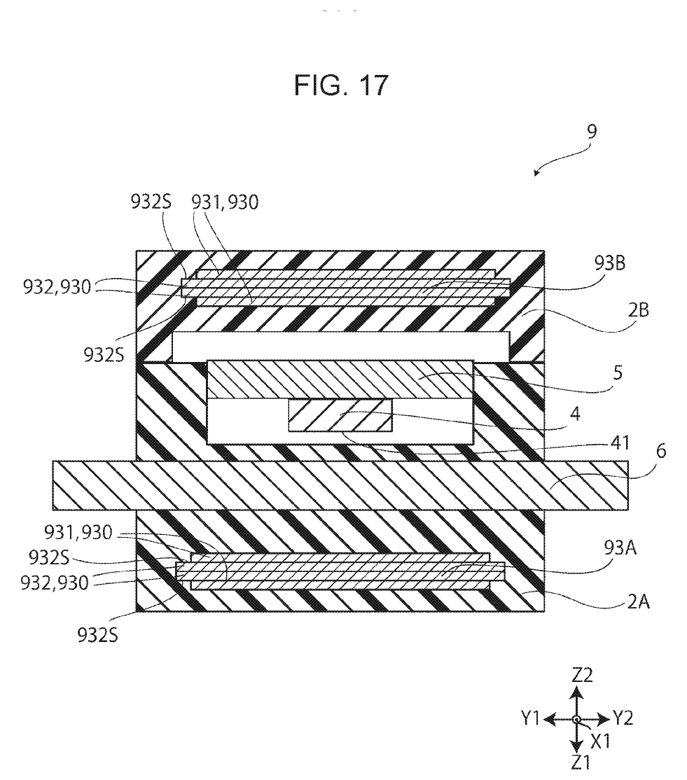

FIG. 16 is a perspective view illustrating the appearance of a current sensor 9 in this embodiment. FIG. 17 a sectional view schematically illustrating the structure of the current sensor 9 as taken along line XVII-XVII in FIG. 16.

The current sensor 9 differs from the current sensor 1 in that the current sensor 9 does not have the core member 3 but has magnetic shields 93A and 93B as a soft magnetic body. Another difference from the current sensor 1 is that the current sensor 9 includes the bus bar 6 and has the case 2 composed of a main body 2A to which the magnetic shield 93A is insert-molded and of a cover 2B to which the magnetic shield 93B is insert-molded.

The magnetic sensor 4 detects magnetism generated by the bus bar 6 when a current under test flow. The magnetic sensor 4 is disposed on the substrate 5 so as to face the bus bar 6 in the Z direction. The magnetism detection surface 41 of the magnetic sensor 4 directly faces the bus bar 6. The sensitivity axis is oriented in a direction parallel to the magnetism detection surface 41. In the vicinity of the magnetism detection surface 41 of the magnetic sensor 4, a magnetic field generated when a current under test flows in the bus bar 6 includes a large X‑direction component near the magnetic sensor 4. Therefore, when the magnetic sensor 4 is placed so that the sensitivity axis becomes parallel to the X direction, magnetism generated by the bus bar 6 can be precisely detected.

The magnetic shields 93A and 93B are placed so as to sandwich the magnetic sensor 4 and bus bar 6 in the Z direction. Soft magnetic bodies such as metal plate-like bodies are used. Since magnetic noise to the magnetic sensor 4 can be suppressed by the magnetic shields 93A and 93B, measurement precision of the current sensor 9 is improved. The current sensor 9 may have only one of the magnetic shields 93A and 93B.

The magnetic shields 93A and 93B each have soft magnetic material plates 931 (first soft magnetic material plates) and soft magnetic material plates 932 (second soft magnetic material plates). The soft magnetic material plate 932 differs in shape from the soft magnetic material plates 931. The soft magnetic material plate 932 has an exposed portion 932S that is exposed without being covered by the soft magnetic material plate 931 when viewed along the Z direction, which is the lamination direction of soft magnetic material plates 930. The soft magnetic material plate 930 in the outermost layer of the magnetic shields 93A and 93B is the soft magnetic material plate 931 both on the Z1 side and on the Z2 side. However, the outermost layer on the surface on at least one of the Z1 side and Z2 side only needs to be the soft magnetic material plate 931, as described as a variation in the first embodiment.

When soft magnetic material plates 930 having a thin thickness are laminated as the magnetic shields 93A and 93B, their properties are improved. It suffices to appropriately design the number of laminated layers and the thickness of the soft magnetic material plate 930 in relation to required performance.

The magnetic shields 93A and 93B are also positioned by the pressing pins 71 in the mold 7 when the magnetic shields 93A and 93B are respectively insert molded to the cover 2B and main body 2A of the case 2, as in the core member 3. In this case, when the exposed portion 932S of the soft magnetic material plate 932, rather than the soft magnetic material plate 931 in the outermost layer in the lamination directions of the magnetic shields 93A and 93B, are sandwiched by the pressing pins 71, positional deviation can be suppressed during insert molding, as in the core member 3. Therefore, the current sensor 9 can be provided with a drop in measurement precession suppressed, the drop being caused by positional deviation of the magnetic shields 93A and 93B.

The embodiments disclosed in this description are exemplary in all points. The present invention is not restricted to these embodiments. The scope of the present invention is not indicated by the description of only the embodiments described above but is indicated by the scope of the claims. It is intended that meanings equivalent to the scope of the claims and all modifications in the scope are included.

The present invention controls a power supply system in a vehicle or the like that has various units. Therefore, the present invention is useful as, for example, a current sensor that measures currents under test that flow in the units and as the method of manufacturing the current sensor.

What is claimed is:

1. A current sensor comprising:
a case;
a soft magnetic body insert-molded to the case, the soft magnetic body being formed by laminating a plurality of soft magnetic material plates; and
a magnetic sensor that measures magnetism; wherein
the soft magnetic body has a first soft magnetic material plate and a second soft magnetic material plate that differs in shape from the first soft magnetic material plate,
the second soft magnetic material plate has an exposed portion exposed without being covered by the first soft magnetic material plate when viewed from a lamination direction of the soft magnetic material plate,
an outermost layer on at least one surface of the soft magnetic body is the first soft magnetic material plate,
the case has a concave portion on a surface of the case, the surface intersecting the lamination direction of the soft magnetic material plates,
the exposed portion is exposed at a deepest portion of the concave portion,
the soft magnetic body has
a plurality of non-exposed layers, in each of which first soft magnetic material plates are laminated together, and
an exposed layer composed of a second soft magnetic material plate, and
the non-exposed layer is laminated on at least one side of the exposed layer.

2. The current sensor according to claim 1, wherein:
the soft magnetic body is a core member; and
the magnetic sensor measures magnetism collected by the core member.

3. The current sensor according to claim 1, wherein the soft magnetic body is a magnetic shield.

4. The current sensor according to claim 1, wherein in each of the non-exposed layer and the exposed layer, a plurality of soft magnetic material plates are laminated.

5. The current sensor according to claim 1, wherein the non-exposed layer is disposed on each of both ends of the exposed layer, which is sandwiched between exposed portions, in the lamination direction of the soft magnetic material plates.

6. The current sensor according to claim 5, wherein in the non-exposed layer disposed on each of both sides of the exposed layer in the lamination direction of the soft magnetic material plates, the number of laminated layers of the first soft magnetic material plates is the same.

7. The current sensor according to claim 1, wherein the exposed layer is composed of one second soft magnetic material plate.

8. The current sensor according to claim 1, wherein:
the soft magnetic body is a core member;
the core member is formed in a ring shape having a cutout;
the case has an insertion hole that extends through an interior of a ring formed in the core member; and
the magnetic sensor is placed inside or near the cutout.

9. The current sensor according to claim 8, wherein:
the magnetic sensor is a magnetoresistive (MR) sensor capable of detecting magnetism in a direction parallel to a magnetism detection surface; and
the magnetism detection surface is placed outside the cutout so that the magnetism detection surface becomes parallel to a separation direction in the cutout.

10. The current sensor according to claim 1, wherein the case has a covering portion placed inside the concave portion, the covering portion covering the exposed portion exposed at the concave portion.

11. A method of manufacturing a current sensor in which a soft magnetic body, which is formed by laminating a plurality of soft magnetic material plates, is insert-molded to a case, wherein:
the soft magnetic body has
a first soft magnetic material plate, which is disposed in an outermost layer on at least one surface, and
a second soft magnetic material plate that differs in shape from the first soft magnetic material plate, the second soft magnetic material plate having an exposed portion exposed without being covered by the first soft magnetic material plate;
when a pair of pressing pins included in a molding mold hold the soft magnetic body, at least one of the pair of pressing pins is brought into contact with the exposed portion; and
a molten molding resin is filled into the molding mold in a state in which at least one of the pair of pressing pins is in contact with the exposed portion.
